(19) United States
(12) Patent Application Publication
(10) Pub. No.: US 2014/0096713 A1
(43) Pub. Date: Apr. 10, 2014

(54) APPARATUS FOR FLOAT GROWN CRYSTALLINE SHEETS

(71) Applicant: VARIAN SEMICONDUCTOR EQUIPMENT ASSOCIATES, INC., Gloucester, MA (US)

(72) Inventors: Frank Sinclair, Quincy, MA (US); Peter L. Kellerman, Essex, MA (US)

(73) Assignee: VARIAN SEMICONDUCTOR EQUIPMENT ASSOCIATES, INC., Gloucester, MA (US)

(21) Appl. No.: 13/647,552

(22) Filed: Oct. 9, 2012

(51) Int. Cl. C30B 15/06

(52) U.S. Cl. 117/13; 117/217

(57) ABSTRACT

An apparatus for forming a crystalline sheet from a melt may include a crucible to contain the melt. The apparatus may also include a cold block configured to deliver a cold region proximate a surface of the melt, the cold region operative to generate a crystalline front of the crystalline sheet and a crystal puller configured to draw the crystalline sheet in a pull direction along the surface of the melt, wherein a perpendicular to the pull direction forms an angle with respect to the crystalline front of less than ninety degrees and greater than zero degrees.

### STATEMENT AS TO FEDERALLY SPONSORED RESEARCH OR DEVELOPMENT

The U.S. Government has a paid-up license in this invention and the right in limited circumstances to require the patent owner to license others on reasonable terms as provided for by the terms of contract number DE-EE0000595 awarded by the U.S. Department of Energy.

### BACKGROUND OF THE INVENTION

1. Field of the Invention

Embodiments of the invention relate to the field of substrate manufacturing. More particularly, the present invention relates to a method, system and structure for growing a crystal sheet from a melt.

2. Discussion of Related Art

Semiconductor materials such as silicon or silicon alloys can be fabricated as wafers or sheets for use in the integrated circuit or solar cell industries among other applications. Demand for large area substrates, such as solar cells, continues to increase as the demand for renewable energy sources increases. One major cost in the solar cell industry is the wafer or sheet used to make these solar cells. Reductions in cost to the wafers or sheets will, consequently, reduce the cost of solar cells and potentially make this renewable energy technology more prevalent.

One type of technology that shows potential for producing cost effective large area substrates entails the growth of crystalline sheets from a melt. In particular, the production of sheets (or “ribbons”) that are horizontally drawn from a melt has been investigated over the past several decades. In particular, techniques, such as so-called floating silicon method (FSM), horizontal ribbon growth (HRG), and low angle silicon sheet method have been studied for the purposes of developing a rapid and reliable method for growing high quality sheets of crystalline semiconductor material, typically silicon. In all of these approaches, the sheet of semiconductor material is drawn in a direction that is perpendicular to the leading edge of the growing crystalline material.

FIG. 1 depicts a system 100 for horizontal ribbon growth arranged according to the prior art. The system 100 includes a crucible 102 that is heated to a temperature sufficient to melt material, which is then drawn as a horizontal sheet 106 or “ribbon” from the system 100. For growth of silicon, the temperature of a melt 104 in the crucible may be set to be slightly above the melting temperature of silicon. For example, the temperature of the melt 104 in the lower region 108 may be several degrees above the melting temperature of the material forming the melt 104. Growth of the horizontal sheet 106 may start when an initiator 110, or “initializer,” is brought into proximity with the top surface of the melt 104, which may cause removal of heat from the surface of the melt 104. In the example shown, the initiator 110 is movable along a direction 112 that is perpendicular to the surface of the melt 104.

According to the prior art, at least a portion of the initiator is maintained at a temperature below the melting temperature of the melt 104. When the initiator 110 is brought close enough to the surface of the melt 104 the cooling provided by the initiator 110 causes crystallization to take place along a growth interface 114 shown in FIG. 1. A growing crystalline sheet 106 may then be pulled along the pull direction 116. The pull velocity along the pull direction 116 may be adjusted so that a stable crystalline front, or leading edge 118 of the horizontal sheet 106 results. As illustrated in FIG. 1, the leading edge 118 is oriented perpendicularly to the pull direction 116. As long as the pull velocity does not exceed the growth velocity of the leading edge 118, a continuous sheet 106 of material may be drawn using the system 100.

Various efforts to model the type of horizontal sheet growth depicted in FIG. 1 have been performed. In one case, Monte Carlo analysis has shown that the growth velocity of a crystalline sheet is limited by processes occurring at the atomic level. Two different growth regimes have been identified: atomically rough growth and faceted growth. In the case of atomically rough growth, the crystal growth velocity is found to be proportional to the amount of undercooling of the melt on the order of 1 cm/s for each 10 K undercooling. In the simulation of faceted growth, the velocity of an individual layer step across the facet is on the order of 0.5 m/s per degree of undercooling. Actual growth velocity (V_{g}) depends on the rate of initiation of new steps, which is not estimated in the latter calculations.

As seen from the above results, it may be useful to increase undercooling of the melt near the growing crystal interface in order to increase V_{g}. However, according to prior art techniques, the maximum pull rate Vₚ is still limited to values that are less than or equal to V_{g} which therefore places an upper limit on the rate of substrate fabrication for a given achievable undercooling conditions. In view of the above, it will be appreciated that there is a need for an improved apparatus and method to increase the rate for producing horizontally grown silicon sheets from a melt.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one example, an apparatus for forming a crystalline sheet from a melt is provided. The apparatus includes a crucible to contain the melt. The apparatus also includes a cold block that is configured to deliver a cold region that is proximate a surface of the melt. The cold region is operative to generate a crystalline front of the crystalline sheet. The apparatus also includes a crystal puller that is configured to draw the crystalline sheet in a pull direction along the surface or the melt. In particular, a perpendicular to the pull direction forms an angle with respect to the crystalline front of less than ninety degrees and greater than zero degrees.

In a further example, a method for forming a crystalline sheet from a melt, includes heating material in a crucible to form the melt. The method further includes providing a cold region of a cold block at a first distance from a surface of the melt. The cold region is operative to generate a crystalline front of the crystalline sheet. The method also includes pulling the crystalline sheet along the surface of the melt in a pull direction, wherein a perpendicular to the pull direction forms an angle greater than zero degrees and less than ninety degrees with respect to the crystalline front.

### BRIEF DESCRIPTION OF THE DRAWINGS

FIG. 1 depicts a system for horizontal ribbon growth of a crystalline material from a melt in accordance with the prior art.

FIG. 2 depicts a perspective view of an apparatus for growing a crystalline sheet from a melt consistent with various embodiments.

FIG. 3a depicts a top view of the apparatus of FIG. 2.

FIG. 3b depicts a top view of another apparatus consistent with additional embodiments.

FIG. 4a depicts details of geometrical features of fabrication of a crystalline sheet from a melt consistent with the prior art.

FIG. 4b depicts details of geometrical features of fabrication of a crystalline sheet from a melt consistent with some embodiments.

FIG. 5 depicts a perspective view of another apparatus for growing a crystalline sheet from a melt consistent with various embodiments.

FIG. 6 depicts a top view of the apparatus of FIG. 5, including an enlarged view of a portion of the apparatus.

FIG. 7 depicts details of geometrical features of fabrication of a crystalline sheet from a melt consistent with the additional embodiments.

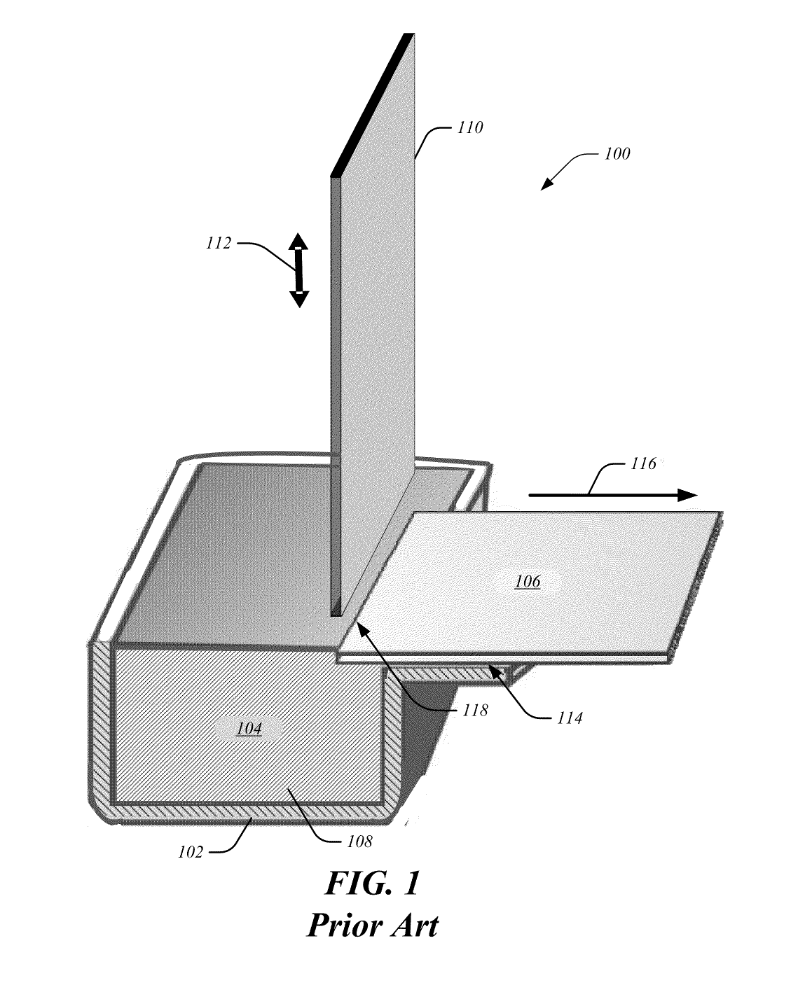

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

To solve the deficiencies associated with the methods noted above, the present embodiments provide novel and inventive apparatus and techniques for horizontal melt growth of a crystalline material, in particular, a monocrystalline material. In various embodiments apparatus and techniques for enhanced formation of a sheet of monocrystalline silicon by horizontal melt growth are disclosed. The apparatus disclosed herein may form long monocrystalline sheets that may be extracted from a melt by pulling, flowing, or otherwise transporting the sheets in a generally horizontal direction. The melt may flow with the sheet in one embodiment, but also may be still with respect to the sheet. Such apparatus may be referred to as horizontal ribbon growth (HRG) or floating silicon method (FSM) apparatus because a thin monocrystalline sheet of silicon or silicon alloys is removed from the surface region of a melt and may form solid sheets that can be pulled in a given direction along the surface of the melt so as to attain a ribbon shape in which long direction of the ribbon is aligned along, for example, the pulling direction.

In HRG techniques, as disclosed above, a growing crystalline front may be generated when a surface of a silicon melt is undercooled below a melting temperature Tₘ. Whichever model among the aforementioned growth models is most applicable to horizontal growth of sheets of silicon from a melt, the results suggest that the physical properties of silicon, taken together with the amount of undercooling that can be delivered to a growth front of the growing crystal, are believed to place a limit on the achievable crystal pulling rate. In particular, the amount of undercooling at a surface of the silicon melt that is delivered by an apparatus may set the growth velocity V_{g} at the crystalline front from which the crystalline sheet is extracted. The present embodiments take advantage of novel configurations of cooling apparatus to initiate and sustain horizontal growth of a crystalline sheet in a manner that increases the crystal pulling rate for a given degree of undercooling as compared to prior art apparatus and techniques. In particular, techniques and apparatus are disclosed herein that provide a crystal pulling rate (velocity) Vₚ that, in contrast to prior art technology, exceeds the growth rate at the crystalline front.

In various embodiments, an apparatus for forming a crystalline sheet from a melt includes a cold block and crystal puller that are interoperable so that a crystalline front of the crystalline sheet that is generated by the cold block forms at a non-zero angle with respect to a perpendicular to the direction of pulling of the crystalline sheet. In this manner, as detailed below, the pulling velocity of the crystalline sheet may exceed the growth velocity at the crystalline front, thereby producing a higher rate of crystalline sheet pulling.

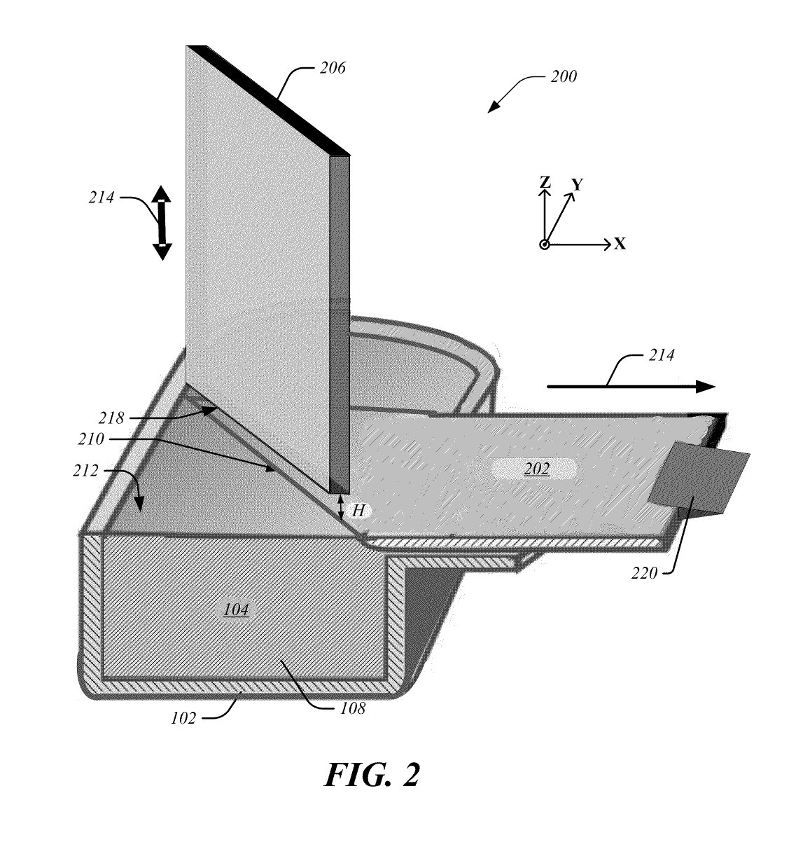

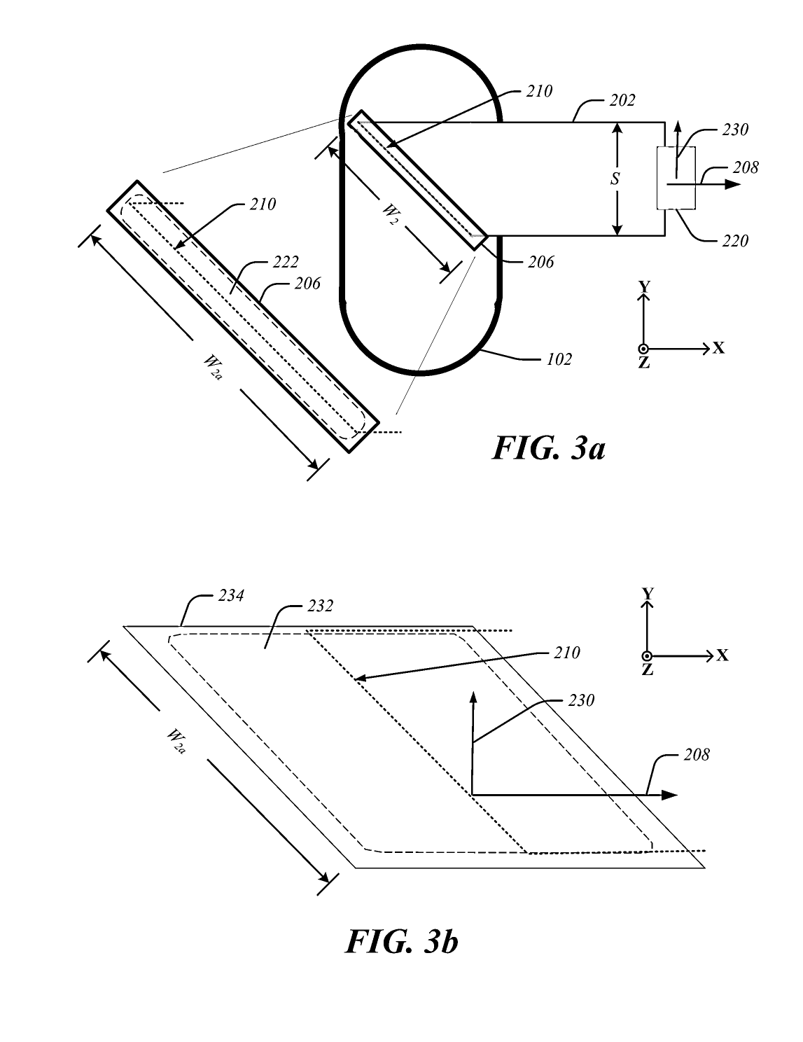

FIG. 2 depicts a perspective view and FIG. 3a shows a top view of an apparatus 200 consistent with various embodiments. The apparatus 200 includes a crucible 102 that is used to melt a material such as silicon to form a melt 104 from which a crystalline sheet 202 is drawn. The apparatus may include components as generally known in the prior art including the crucible 102 and heating components (not shown) that are used to heat the melt 104 and/or crucible 102. In embodiments of silicon growth, the temperature of the melt 104, such as in the lower region 108 may be maintained in a range slightly in excess of the melting temperature (Tₘ) of silicon, such as several degrees above the value of Tₘ for silicon. In order to initiate solidification of material from the melt 104, the apparatus 200 includes a cold block 206 that is operative to deliver a cooling region proximate a portion of the surface 212 of the melt 104. In one example, the cold block 206 is provided with fluid cooling (not shown) internal to the cold block to create a region within the cold block 206 that is colder than the surface 212. As illustrated, the cold block 206 is movable along a direction 214 such that the height H, that is, the shortest distance between lower surface 218 and surface 212 of the melt 104, can be adjusted. When the value of H is sufficiently small, the cold block 206 may provide a cold region in the lower surface 218 that is sufficient to cause portions of the melt 104 nearby to solidify. When crystallization takes place a crystalline front 210 may form and grow with a growth velocity V_{g} that is proportional to T_{c}⁴-Tₘ⁴, where T_{c} is the temperature of the cold region of the cold block 206 proximate the surface 212 of the melt 104. Thus, if the cold block 206 maintains a cold region temperature T_{c} sufficiently low and the cold block 206 is sufficiently close to the surface 212, crystalline material that can be drawn into a crystalline sheet grows in the region of the surface 212 proximate the cold block 206.

Consistent with the known art, a crystal puller 220 may include a crystalline seed (not separately shown) that is drawn back and forth along a given direction, such as parallel to the X-axis of the Cartesian coordinate system shown in FIG. 2. A crystalline sheet 202 may then be drawn from the melt 104 when a precipitating layer attaches to the crystalline seed. As illustrated in FIG. 2, the crystalline sheet 202 is drawn from a region of the melt 104 proximate a lower surface of the cold block 206 when the crystal puller 220 pulls a layer of crystalline material along the pull direction 214, which is parallel to the X-axis. The layer of crystalline material may be drawn as a crystalline sheet 202 until a desired amount of the crystalline sheet 202 has been produced. Subsequently, the cold block 206 may be moved away from surface 212 along the direction 214 to a distance that is further from the surface 212 of melt 104. At the further distance, the cold block 206 may no longer provide sufficient cooling to the surface 212 to cause crystallization of the melt 104, or V_{g} may decrease to a value that is insufficient to support sustained pulling of the crystalline sheet 202. The crystalline front 210 then terminates from under the cold block 206 and the crystalline sheet 202 no longer grows.

In particular, as illustrated in FIG. 3a, when the cold block 206 is sufficiently close to the surface 212, and the crystalline sheet 202 is drawn along the pull direction 208, the crystalline front 210 arises in a region of the surface 212 of melt 104 that is proximate the lower surface 218 of the cold block 206. As depicted in the inset of FIG. 3a, the cold block 206 has a generally elongated shape as viewed in the X-Y plane parallel to the surface 212. The cold block therefore may generate a cold region 222 that is elongated and has a shape similar to that of the lower surface of the cold block 206. This cold region 222 may then generate a crystalline front 210 along a line that is parallel to a long direction of the (elongated) lower surface 218. It is to be noted that, although visible in the top view of FIG. 3a for the purposes of illustration, the cold region 222 is disposed on the lower surface 218 of the cold block 206 that is proximate the surface 212 shown in FIG. 2.

As further shown in FIG. 3a, the cold region 222 has a width W₂ₐ parallel to the elongated direction, which produces an equivalent width in the crystalline front 210. However, as shown in FIG. 3a, unlike prior art techniques and apparatus, the apparatus 200 produces a crystalline front 210 with an orientation that is not perpendicular to the pull direction 208, but rather forms an angle greater than zero degrees and less than ninety degrees with respect to a perpendicular 230 to the pull direction 208.

FIG. 3b depicts a top view of another cold block 234 consistent with additional embodiments. In this case, the cold block does not have a generally elongated shape as viewed in the X-Y plane parallel to the surface 212. The cold block 234 generates a cold region 232 that is also not elongated and has a shape similar to that of the lower surface of the cold block 234. However, as with the cold region 222, the cold region 232 is operative to generate a cold front 210 that forms an angle greater than zero degrees and less than ninety degrees with respect to the perpendicular 230 to the pull direction 208. Advantages of the configuration of a cold block illustrated in FIGS. 3a, 3b for growing a sheet of material such as silicon are detailed with respect to the FIGs. to follow.

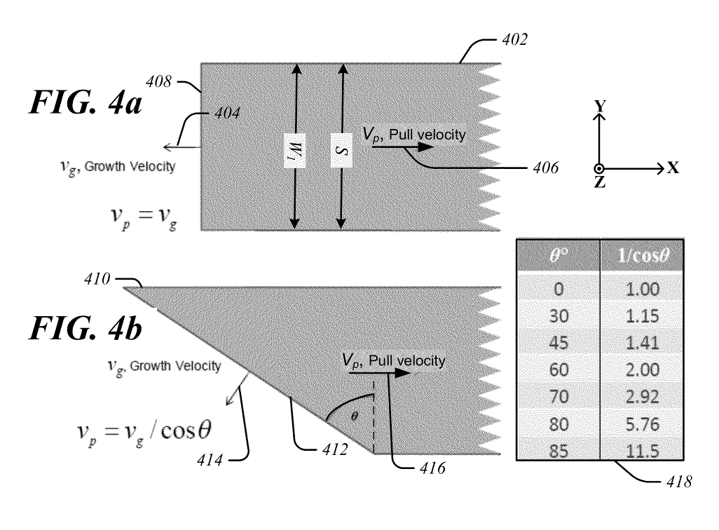

FIGS. 4a and 4b present a comparison of details of the geometry for fabrication of crystalline sheets from a melt consistent with the prior art and present embodiments, respectively. In particular, a top down view is illustrated using the same Cartesian coordinate system as in FIGS. 2 and 3 for reference. In FIG. 4a there is shown a top down view of a crystalline sheet 402 that may be formed in an apparatus consistent with the prior art. In particular, a cold block (not shown for clarity) creates a crystalline front 408 that lies along a direction parallel to the Y-axis, in other words, along the perpendicular to the pulling direction. The crystalline sheet 402 is drawn by pulling along the direction 406 parallel to the X-axis. Crystalline material may form at the crystalline front 408 with a tendency to grow along the direction 404 to the left as shown in FIG. 4a, with a growth velocity V_{g}, which may be on the order of centimeters per second in some cases. Of course crystalline material may also grow with a velocity parallel to the Z-direction. At the same time, crystalline sheet material may be drawn along the direction 406 with a pulling velocity Vₚ. As illustrated, the direction 406 is oriented 180 degrees from the direction 404 of growth of the crystalline front 408. The value of the pulling velocity Vₚ to be used to extract the crystalline sheet 402 may in part be determined by the value of V_{g}. For example, as long as the magnitude of Vₚ does not exceed that of V_{g}, the crystalline front 408 propagates in the direction 404 sufficiently rapidly to counteract the pulling of sheet material at the pulling velocity Vₚ along the direction 406. Accordingly, the crystalline front 408 may remain stable in a position proximate a cold block (not shown) that causes the solidification, and a continuous sheet 402 may be pulled from the melt 104. In this manner it can be seen that the magnitude of V_{g} places an upper limit on the pulling velocity for extracting a crystalline sheet 402.

In FIG. 4b, there is shown a top down view of a crystalline sheet 410 that may be formed in an apparatus consistent with the present embodiments. In the convention illustrated in FIG. 4b, for the purposes of comparison to the prior art techniques, the crystalline sheet 410 is drawn by pulling along a direction 416 that is also parallel to the X-axis. Again for purposes of comparison, it may be assumed that the growth velocity V_{g} of the crystalline front 412 has the same value as that in the prior art example of FIG. 4a. However, unlike the prior art, a cold block (not shown for clarity, but see FIG. 3A) creates the crystalline front 412 with an orientation that lies along a direction that forms a non-zero angle θ with respect to the Y-axis. The crystalline material thus formed along the crystalline front 412 has a tendency to grow along the direction 414 downwardly and to the left as shown in FIG. 4b.

If the crystalline material in FIG. 4b is assumed to grow with a velocity V_{g} along the direction 414, when the crystalline sheet 410 is pulled along the direction 416, the pulling velocity Vₚ may exceed V_{g} without causing a change in the position of the crystalline front 412. In particular, as illustrated in FIG. 4b, if Vₚ=V_{g}/cos θ the position of crystalline front 412 may remain stable. Referring again to FIGS. 2 and 3, in this manner, by orienting a long axis of the cold block 206 at an angle θ with respect to the perpendicular to the pulling direction, the present embodiments provide a substantial enhancement of Vₚ over prior art techniques. FIG. 4b also lists exemplary enhancement factors 418, which express the relative increase in Vₚ that is achievable as a function of angle θ when a cold block is configured in accordance with the present embodiments. For example, when θ is equal to 45 degrees, a 41% enhancement in Vₚ is achieved, while at a value of θ equal 60 degrees a doubling in Vₚ is achieved. It is to be noted that in order to maintain the same sheet width S of a crystalline sheet, as in the case of a prior art apparatus, the width of the cold block in the elongated direction is increased with respect to the prior art apparatus. As illustrated, for example, in FIG. 4a, in a prior art apparatus, a width W₁ of a cold block (not shown) is the same as the sheet width S. In contrast, and as shown in FIG. 3A, the width W₂ of a cold block 206 is greater than the sheet width S.

In addition to enhancing the pull rate for horizontally drawn crystalline sheets, the present embodiments afford additional advantages. For example, during crystallization from a melt, defects or contaminants may become entrained in eddies that form in the melt surface near the lower surface of a cold block. By orienting the cold block so that the elongated direction forms an angle θ with respect to the pull direction, any defects or contaminants may be swept toward the “downstream” end of the cold block, thereby potentially removing such defects or contaminants from portions of the sheet that may be later used to fabricate substrates.

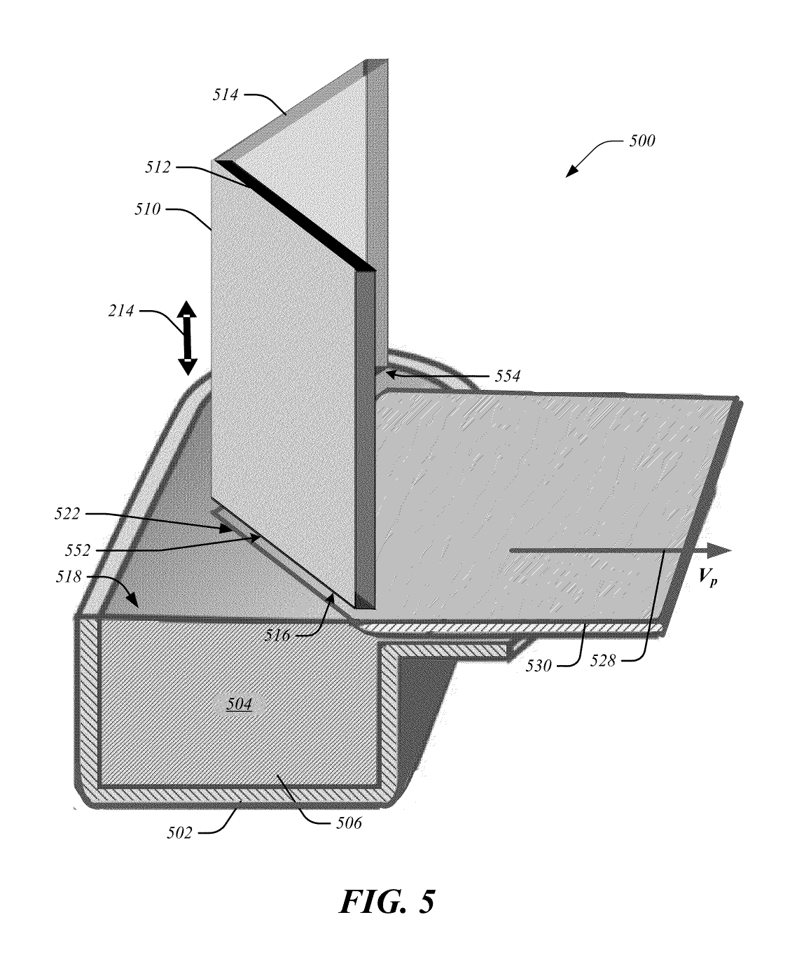

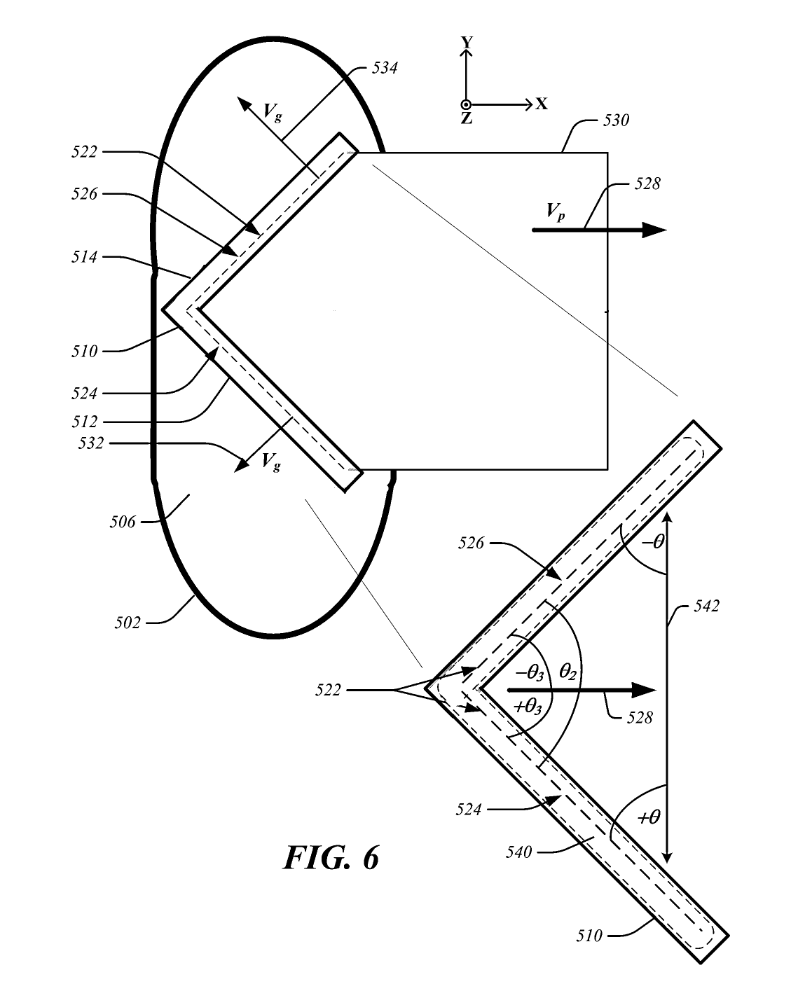

FIG. 5 depicts a perspective view and FIG. 6 shows a top view of an apparatus 500 consistent with various additional embodiments. In this example, crucible 502 contains a melt 504, in which at least the lower portion 506 is maintained above a melting temperature of material to form a crystalline sheet 530. The cold block 510 has a “V” shape when viewed from a top perspective shown in FIG. 6. In particular the cold block 510 includes portions 512 and 514 that each has an elongated shape that together form a V as viewed from the top. The lower surface of cold block 510 may thus deliver a cold region 540 that has a generally V shaped pattern, as illustrated in the insert in FIG. 6. It is to be noted that, although visible in the top view of FIG. 6 for the purposes of illustration, the cold region 540 is disposed on the lower surface 516 of the cold block 510 that is proximate the surface 518 shown in FIG. 5.

When the lower surface 516 is sufficiently close to the surface 518 of the melt 504, the cold region 540 may generate a V-shaped crystalline front 522. The V-shaped crystalline front 522 may be characterized as a combination of two portions or crystalline fronts 524 and 526, as also depicted in FIG. 6. Crystalline material forming along the crystalline fronts 524, 526 may be drawn along the surface 518 in the pull direction 528 to form the crystalline sheet 530.

As shown in FIG. 6, the crystalline front 524 has a tendency to grow along the direction 532 downwardly and to the left as shown in FIG. 6, while the crystalline front 526 has a tendency to grow along the direction 534 upwardly and to the left as also shown in FIG. 6. Assuming that the degree of cooling provided by the portion 512 is the same as that provided by the portion 514, the growth velocity V_{g} of crystalline front 524 may equal that of crystalline front 526. Unlike the crystalline front 408 produced by a prior art apparatus, and similar to the crystalline front 412, the crystalline fronts 524, 526 each form a non-zero angle with respect to the perpendicular 542 to the pull direction 528. In particular, the crystalline front 524 may form an angle +θ while the crystalline front 526 forms an angle −θ, each with respect to the perpendicular 542. Thus, under stable crystal pulling conditions in which the crystalline fronts 524, 526 remain stationary and a continuous crystalline sheet 530 is formed, the pull rate Vₚ of the crystalline sheet 530 along the pull direction 528 may exceed V_{g} according to the enhancement factors 418 set forth in FIG. 4b. In various embodiments, in order to form a uniform sheet of crystalline material, the cold block 510 is arranged with respect to the pull direction 528 such that the angles −θ and +θ are the same value. Another way to express this condition is to consider the angle θ₂ between the crystalline fronts 524, 526. When −θ and +θ are the same value the pull direction 528 bisects the angle θ₂ between the fronts, thereby forming angles of equal value +θ₃ and −θ₃ between the pull direction 528 and respective crystalline fronts 524 and 526.

Moreover, in order to grow a uniform sheet of material using the V-shaped configuration of a cold block, the lower surfaces 552 and 554 of respective portions 512 and 514 of the cold block 510 may be configured to be coplanar and parallel to the surface 518. Thus, the lower surfaces 552 and 554 may be equally spaced from the surface 518, thereby providing the equivalent degree of cooling to the surface 518 and consequently imparting equal values of V_{g} to the crystalline fronts 524, 526.

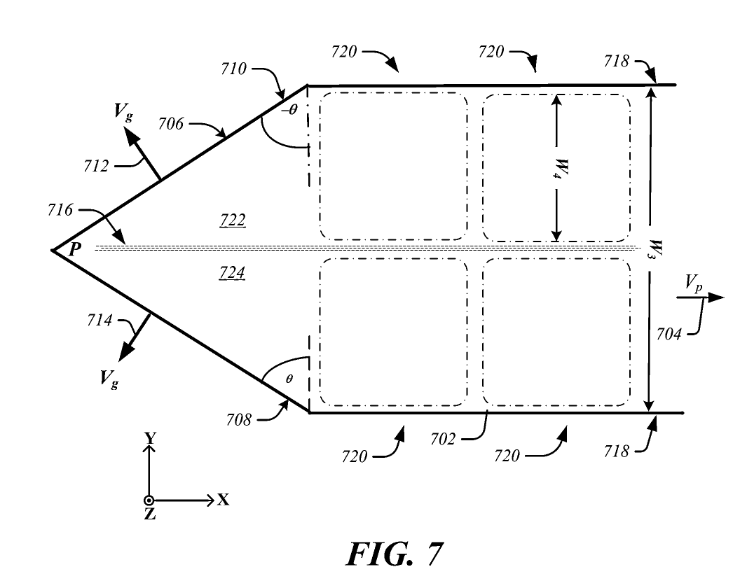

FIG. 7 depicts a top view that includes further details of the geometry of crystal growth when a V-shaped cold block as described in FIGS. 5 and 6 is used to initiate crystallization. As illustrated, a crystalline sheet 702 is pulled along the pull direction 704 while a cold block (not shown) produces crystalline fronts 706 and 708 that define a V-shaped crystalline front 710. The crystalline fronts 706, 708 grow in the respective directions 712, 714, such that the pull velocity Vₚ exceeds the growth rate V_{g} of the crystalline fronts 706, 708 under stable growth conditions. Because the direction of crystalline front 710 shows an abrupt change where the individual crystalline fronts 706, 708 meet at point P, defects may precipitate in a region near the point P. During pulling of the crystalline sheet 702, this results in a generally linearly shaped region 716 that forms in an interior region of the crystalline sheet 702 and is generally parallel to the pull direction 704. Consistent with various embodiments, the overall width of a V-shaped cooling block in a direction parallel to the Y-axis shown is arranged so that the width W₃ of the crystalline sheet 702 (the distance between opposite sides 718) is sufficient so that substrates may subsequently be cut from the crystalline sheet in a manner that does not intersect the region 716. Thus, if it is desired to dice substrates 720 of a given dimension W₄, which may represent a designed substrate width, the dimension W₃ is arranged to be more than twice that of W₄, so that the region 716 is not included in any of the substrates 720.

Although a cold block may be arranged to produce a crystalline front 706 whose width differs from that of the crystalline front 708, it various embodiments, the widths of the crystalline fronts 706, 708 are the same. In this manner, substrates of equal dimension may be conveniently produced from the regions 722, 724 of the crystalline sheet 702 that lie above and below the region 716.

In summary, the present embodiments provide multiple advantages over prior art FSM and HRG apparatus. For one, in comparison to conventional FSM apparatus or HRG apparatus, more rapid crystal pull rates are obtainable for the same degree of undercooling delivered to the melt surface of a material to form a crystalline sheet. Moreover, the same crystal pull rate as a conventional apparatus may be achieved with less undercooling. In other words, a cold block arranged according to the present embodiments may be able to achieve a pull rate the same as a conventional apparatus without having to deliver as great a degree of undercooling to the surface of a melt used by a conventional apparatus, because of the enhancement factor provided by the angled geometry of the cold block with respect to the pull direction.

The present invention is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the subject matter of the present disclosure should be construed in view of the full breadth and spirit of the present disclosure as described herein.

What is claimed is:

1. An apparatus for forming a crystalline sheet from a melt, comprising:
a crucible to contain the melt;
a cold block configured to deliver a cold region proximate a surface of the melt, the cold region operative to generate a crystalline front of the crystalline sheet; and
a crystal puller configured to draw the crystalline sheet in a pull direction along the surface of the melt, wherein a perpendicular to the pull direction forms an angle with respect to the crystalline front of less than ninety degrees and greater than zero degrees.

2. The apparatus of claim 1, the angle being less than forty five degrees.

3. The apparatus of claim 1, the cold block assembly comprising an elongated shape configured to generate a first width in the cold region equal to a second width of the crystalline front.

4. The apparatus of claim 1, the cold block operative to move between a first and second position, the first position being closer to the surface of the melt, wherein a first growth velocity of the crystalline sheet when the cold block is arranged at the first position is greater than a second growth velocity when the cold block is arranged at the second position.

5. The apparatus of claim 1, wherein the crystalline front is a first crystalline front, and wherein the cold block comprises:
a V-shaped structure in a plane parallel to the surface of the melt, the V-shaped structure including a first portion and second portion connected to the first portion,
wherein the first portion is configured to generate the first crystalline front at a first angle with respect to the perpendicular, and
wherein the second portion is configured to generate a respective second crystalline front at a second angle equal in magnitude to the first angle with respect to the perpendicular.

6. The apparatus of claim 5, wherein a third width of the first portion parallel to the first crystalline front is equal to a fourth width of the second portion parallel to the second crystalline front.

7. The apparatus of claim 5, wherein a crystalline sheet pulled from the apparatus has a fifth width along the perpendicular that is greater than or equal to two times a designed substrate width of substrates to be formed from the crystalline sheet.

8. The apparatus of claim 5, wherein a first lower surface of the first portion proximate the melt is coplanar with a second lower surface of the second portion proximate the melt.

9. The apparatus of claim 1, the cold block comprising an internal fluid to maintain a temperature of the cold block below a melting temperature of the melt.

10. A method for forming a crystalline sheet from a melt, comprising:
heating material in a crucible to form the melt;
providing a cold region of a cold block at a first distance from a surface of the melt, the cold region operative to generate a crystalline front of the crystalline sheet; and
pulling the crystalline sheet along the surface of the melt in a pull direction, wherein a perpendicular to the pull direction forms an angle greater than zero degrees and less than ninety degrees with respect to the crystalline front.

11. The method of claim 10, comprising pulling the crystalline sheet at an angle less than forty five degrees with respect to the perpendicular.

12. The method of claim 10, comprising providing the cold region of the cold block as an elongated shape having a first width equal to a second width of the crystalline front.

13. The method of claim 10, wherein the crystalline front is a first crystalline front, the method further comprising:
arranging the cold block as a first portion and a second portion connected to the first portion in a V-shaped configuration in a plane parallel to the surface of the melt;
generating the first crystalline front using the first portion at a first angle with respect to the perpendicular; and
generating a second crystalline front using the second portion at a second angle with respect to the perpendicular, the second angle having a magnitude the same as that of the first angle with respect to the perpendicular.

14. The method of claim 13, further comprising:
arranging a third width to the first portion parallel to the first crystalline front to equal a fourth width of the second portion parallel to the second crystalline front.

15. The method of claim 14, further comprising:
determining a substrate width for substrates to be fabricated from the crystalline sheet; and
arranging the V-shaped configuration to have a fifth width along the perpendicular to equal a value greater than two times the substrate width.

16. The method of claim 13, further comprising arranging a first lower surface of the first portion proximate the melt to be coplanar with a second lower surface of the second portion proximate the melt.

17. The method of claim 10, further comprising:
providing a crystalline seed;
moving the crystalline seed along the surface of the melt to initiate growth; and
pulling the crystalline seed along the first direction after growth of the crystalline sheet is initiated.

18. The method of claim 10, further comprising moving the cold block from the first distance to a second distance from the melt surface greater than the first distance, wherein the crystalline front terminates when the cold block is moved to the second distance.
